(19) United States
(12) Patent Application Publication
(10) Pub. No.: US 2025/0370003 A1
(43) Pub. Date: Dec. 4, 2025

(54) DEVICE

(71) Applicant: YOKOWO CO., LTD., Tokyo (JP)

(72) Inventors: Kouji USUDA, Gunma (JP); Hiroshi KATO, Gunma (JP); Isao YANAGISAWA, Gunma (JP)

(73) Assignee: YOKOWO CO., LTD., Tokyo (JP)

(21) Appl. No.: 18/869,442

(22) PCT Filed: Apr. 14, 2023
(86) PCT No.: PCT/JP2023/015111

§ 371 Date: Nov. 26, 2024

(30) Foreign Application Priority Data
May 26, 2022 (JP) 2022-085756

(51) Int. Cl. G01R 1/04

(52) U.S. Cl. CPC G01R 1/0408

(57) ABSTRACT

A device includes a first member, a second member held by the first member, and a removal portion provided in the first member. The second member holds an object to be held that is brought close to the first member by movement of a pressing member in a first direction. The removal portion moves in a second direction that is different from the first direction in conjunction with the movement of the pressing member in the first direction. When the object to be held moves away from the first member, at least a part of the removal portion overlaps at least a part of the object to be held when viewed in the first direction.

### TECHNICAL FIELD

The present invention relates to a device such as a socket.

### BACKGROUND ART

In the related art, as disclosed in Patent Literature 1, a device including a handler has been proposed.

### CITATION LIST

### Patent Literature

Patent Literature 1: JP2001-242216A

### SUMMARY OF INVENTION

### Technical Problem

However, due to a temperature difference or the like, when a package (an object to be held) may stick to a cold plate (a pressing member) of the handler, and when the cold plate is retracted, the package may be moved together with the cold plate.

Therefore, an example of the object of the present invention is to limit movement of an object to be held. Other objects of the present invention will become apparent based on the description of the present specification.

### Solution to Problem

An aspect of the present invention provides a device including: a first member; a second member held by the first member; and a removal portion provided in the first member, in which the second member holds an object to be held that is brought close to the first member by movement of a pressing member in a first direction, in which the removal portion moves in a second direction that is different from the first direction in conjunction with the movement of the pressing member in the first direction, and in which, when the object to be held moves away from the first member, at least a part of the removal portion overlaps at least a part of the object to be held when viewed in the first direction.

According to the above aspect of the present invention, when viewed from the first direction, at least a part of the removal portion may overlap at least a part of the object to be held, and movement of the object to be held in the first direction may be limited. Accordingly, the object to be held can be prevented from moving together with the pressing member when the object to be held moves away from the first member.

### BRIEF DESCRIPTION OF DRAWINGS

FIG. 1 is an exploded perspective view of a socket according to the present embodiment.

FIG. 2 is a perspective view of a package and the socket before the package is attached.

FIG. 3 is a perspective view of the socket after the package is attached.

FIG. 4 is a perspective view showing a cross section of a portion in FIG. 3 where a first latch is located.

FIG. 5 is a perspective view of a first removal device.

FIG. 6 is a perspective view of a second removal device.

FIG. 7 is a cross-sectional configuration view of the socket, the package, an inspection substrate, and a cold plate in a first state.

FIG. 8 is a cross-sectional configuration view of the socket, the package, the inspection substrate, and the cold plate in a second state.

FIG. 9 is a cross-sectional configuration view of the socket, the package, the inspection substrate, and the cold plate in a third state.

FIG. 10 is a cross-sectional configuration view of the socket, the package, the inspection substrate, and the cold plate in a fourth state.

FIG. 11 is a cross-sectional configuration view of the socket, the package, the inspection substrate, and the cold plate in a fifth state.

FIG. 12 is a cross-sectional configuration view of the socket, the package, the inspection substrate, and the cold plate in a sixth state.

FIG. 13 is a cross-sectional configuration view of the socket, the package, the inspection substrate, and the cold plate in a seventh state.

FIG. 14 is a cross-sectional configuration view of the socket, the package, the inspection substrate, and the cold plate in an eighth state.

FIG. 15 is a cross-sectional configuration view of the socket, the package, the inspection substrate, and the cold plate in a ninth state.

FIG. 16 is a cross-sectional configuration view of the socket, the package, the inspection substrate, and the cold plate in a tenth state.

FIG. 17 is a cross-sectional configuration view of the socket, the package, the inspection substrate, and the cold plate in an eleventh state.

### DESCRIPTION OF EMBODIMENTS

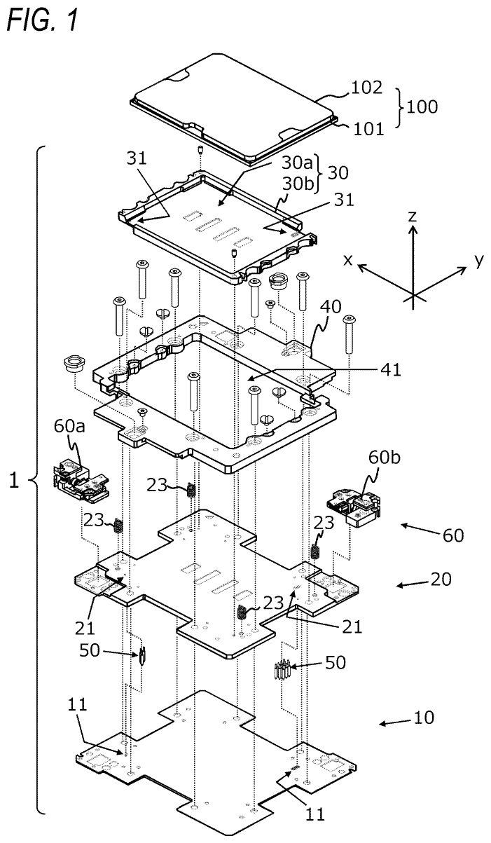

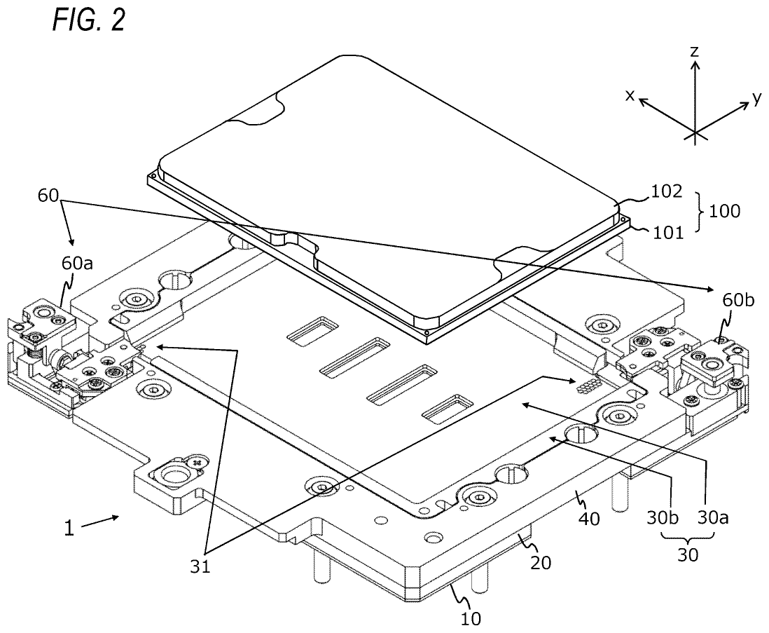

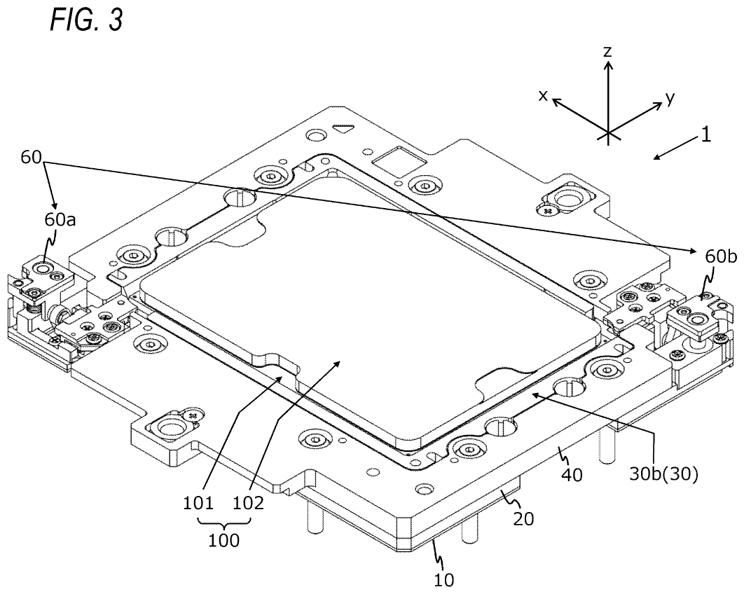

Hereinafter, the present embodiment will be described with reference to FIGS. 1 to 17. Embodiments are not limited to the following embodiment. Contents described in one embodiment are similarly applied to other embodiments in principle. The embodiments and modifications can be combined as appropriate.

In order to describe the directions, one (the front-rear direction) of the horizontal directions is referred to as an x direction, a horizontal direction (the left-right direction) that is perpendicular to the x direction is referred to as a y direction, and a direction (the upper-lower direction) that is perpendicular to the x direction and the y direction is defined as a z direction. In FIG. 1, directions indicated by arrows of xyz axes are defined as a forward direction, a rightward direction, and an upward direction, respectively.

### Socket 1

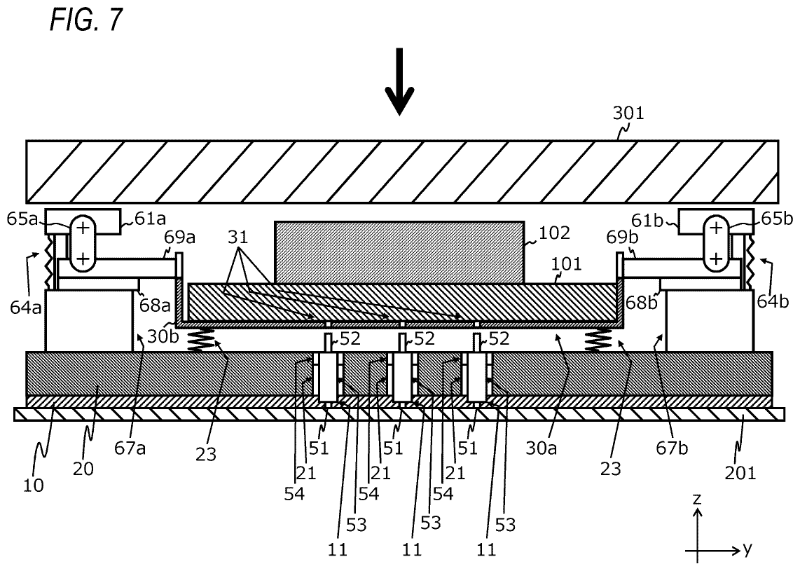

As shown in FIGS. 1 to 4, a socket (a test socket) 1 according to the present embodiment includes a pin plate 10, a pin block 20, a floating plate 30, a contact probe 50, a cover 40, and a removal portion 60. In order to facilitate understanding in the drawing, the contact probe 50 in FIG. 1 is shown larger than other members. The socket 1 is used to inspect an object to be inspected (a package 100) such as a semiconductor integrated circuit. The pin plate 10, the pin block 20, the floating plate 30, and the cover 40 are arranged from the lower side in the z direction toward the upper side in the z direction. A tester (not shown) is provided on the lower side of the socket 1 in the z direction. A handler (not shown) is provided on the upper side of the socket 1 in the z direction. In the drawings (FIGS. 7 to 17) showing an operation procedure to be described later, an inspection substrate 201 that is a part of the tester and a pressing member 301 such as a cold plate that is a part of the handler are shown.

### Pin Plate 10

The pin plate 10 is, for example, a resin plate, and is formed into a substantially rectangular shape. The pin plate 10 has a through hole (a first hole 11) through which the lower end portion (a first plunger 51) of the contact probe 50 passes.

### Pin Block 20

The pin block 20 is a metal plate having a larger thickness in the z direction than the pin plate 10, and is formed into a substantially rectangular shape. The pin block 20 has a through hole (a second hole 21) through which the main body portion (a conductive tube 53 including an internal spring) of the contact probe 50 passes. A plate spring 23 is provided on the upper surface of the pin block 20 in a region that overlaps the floating plate 30 when viewed from the z direction. In order to facilitate understanding in the drawing, the plate spring 23 in FIG. 1 is shown larger than other members. The floating plate 30 is held by the pin block 20 in a state of being movable in the z direction by the biasing force of the plate spring 23.

The removal portion 60 is provided on the upper surface of the pin block 20 outside a region that overlaps the floating plate 30 when viewed from the z direction. In the present embodiment, a first removal mechanism 60a is provided on the front side in the x direction and on the left side in the y direction in the peripheral edge portion of the upper surface of the pin block 20, and a second removal mechanism 60b is provided on the rear side in the x direction and the right side in the y direction. However, as will be described later, a first latch 69a of the first removal mechanism 60a and a second latch 69b of the second removal mechanism 60b move in the y direction. Therefore, the distal end portion of the first latch 69a and the distal end portion of the second latch 69b may have a position relationship of overlapping the floating plate 30 when viewed from the z direction.

### Floating Plate 30

The floating plate 30 is made of, for example, resin, and includes a bottom plate 30a and a frame 30b. The frame 30b extends upward from the peripheral edge portion of the bottom plate 30a in the z direction, and the bottom plate 30a and the frame 30b form a substantial box shape. The bottom plate 30a of the floating plate 30 has a through hole (a third hole 31) through which the upper end portion (a second plunger 52) of the contact probe 50 passes. The first hole 11 of the pin plate 10, the second hole 21 of the pin block 20, and the third hole 31 of the floating plate 30 overlap when viewed from the z direction. The frame 30b surrounds the peripheral edge portion of the bottom plate 30a. However, the frame 30b is omitted in a region facing the first latch 69a or the second latch 69b of the removal portion 60 in the y direction. Therefore, notches are formed in a region of the floating plate 30 that faces the first latch 69a in the y direction and a region of the floating plate 30 that faces the second latch 69b in the y direction. The package 100 is placed on the inside of the frame 30b by a PNP head (a pick and place head, not shown) of a handler or the like.

### Cover 40

The cover 40 covers the peripheral edge portion of the pin block 20 from the upper side in the z direction. The cover 40 has a hole (a housing hole 41) at the center. The floating plate 30 is housed in the housing hole 41.

The pin plate 10, the pin block 20, and the cover 40 are fixed by screwing or the like. The assembly of the pin plate 10, the pin block 20, and the cover 40 is fixed to a tester (not shown) by screwing or the like. When the assembly is fixed to the tester, the inspection substrate 201 of the tester comes into contact with the lower surface of the pin plate 10, and the distal end portion of the first plunger 51 is connected to the inspection substrate 201.

### Contact Probe 50

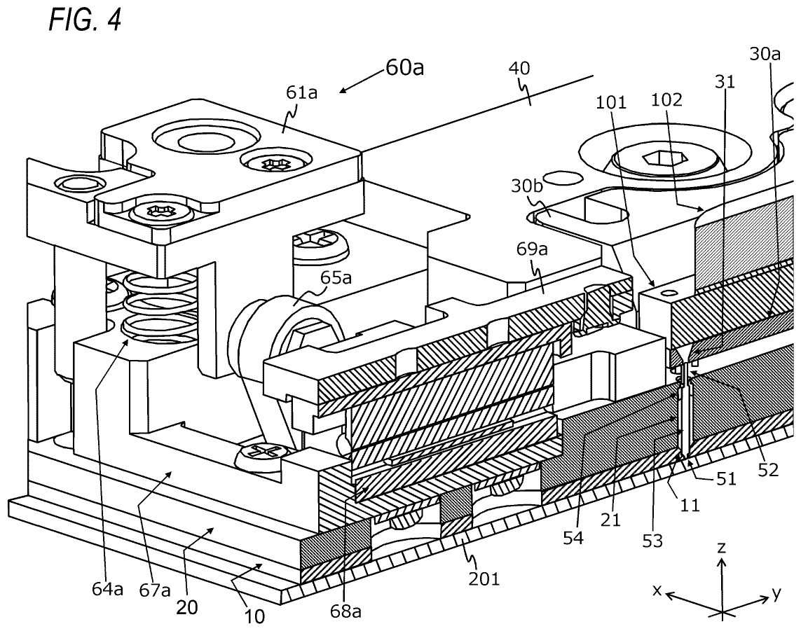

The contact probe 50 includes the first plunger 51, the second plunger 52, and the conductive tube 53. The distal end portion of the first plunger 51 passes through the first hole 11 of the pin plate 10, and is connected to the electrode of the inspection substrate 201 of the tester. The distal end portion of the second plunger 52 passes through the third hole 31 of the floating plate 30, and is connected to the object to be inspected (the electrode of a substrate 101 of the package 100). However, FIG. 4 shows a state in which the floating plate 30 is not lowered and the distal end portion of the second plunger 52 and the electrode of the substrate 101 are not in contact with each other.

The conductive tube 53 is housed in the second hole 21 of the pin block 20, and houses the base end portion of the first plunger 51, the base end portion of the second plunger 52, and a spring (an internal spring, not shown). The internal spring of the conductive tube 53 biases the first plunger 51 and the second plunger 52 in directions that are away from each other. An insulating member 54 is provided between the conductive tube 53 and the inner wall of the second hole 21, and separates the conductive tube 53 from the pin block 20.

### Removal Portion 60

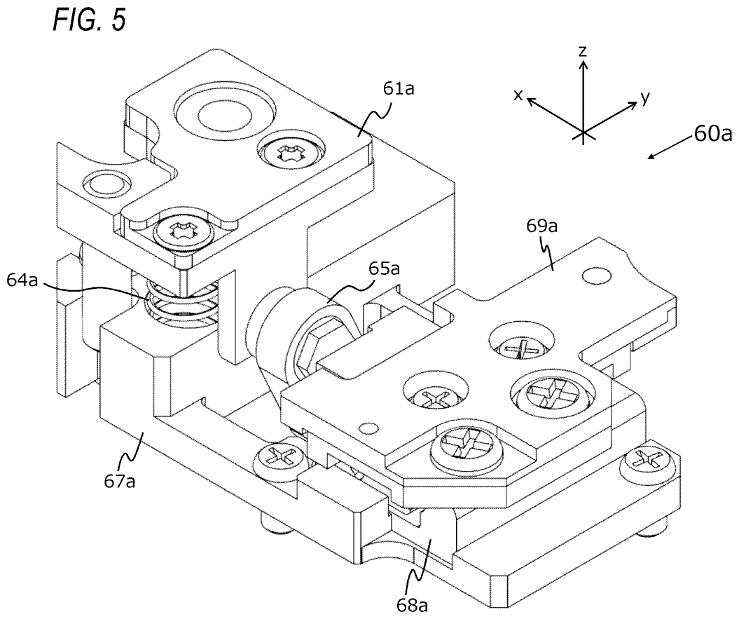

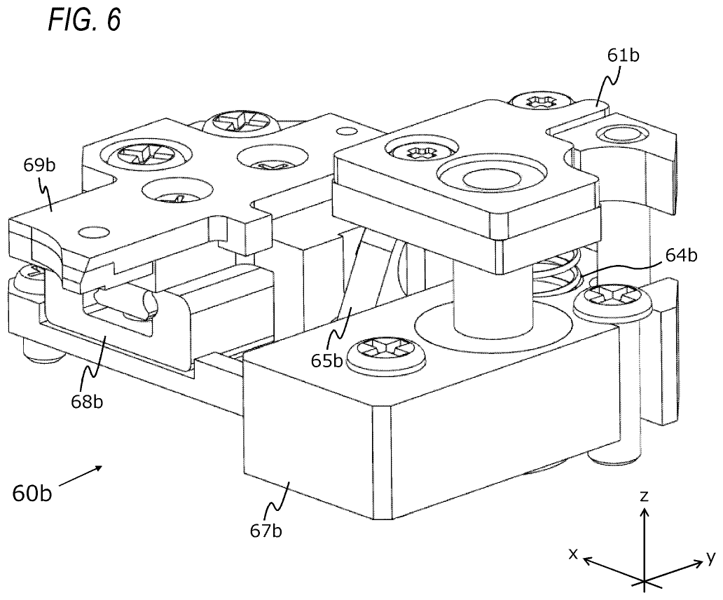

As shown in FIGS. 5 and 6, the removal portion 60 (the first removal mechanism 60a and the second removal mechanism 60b) moves partially in the y direction in conjunction with the movement of the pressing member 301 in the z direction. Accordingly, at least when the package 100 is lifted upward in the z direction by the pressing member 301, the removal portion 60 limits the substrate 101 of the package 100 from moving upward in the z direction.

### First Removal Mechanism 60a

The first removal mechanism 60a includes a first vertical movement portion 61a, a first vertical movement portion spring 64a, a first link 65a, a first base portion 67a, a first latch base 68a, and a first latch 69a (see FIG. 5).

The first vertical movement portion 61a is the upper portion of the first removal mechanism 60a, and is pressed downward in the z direction by the pressing member 301. The first vertical movement portion 61a is held by the first base portion 67a in a state of being movable in the z direction.

The first vertical movement portion 61a is provided in a position relationship satisfying the following conditions. At least a part of the first vertical movement portion 61a overlaps a part of the lower end portion of the pressing member 301 when viewed from the z direction, and the first vertical movement portion 61a does not overlap the lower end portion of the PNP head when viewed from the z direction.

The first vertical movement portion spring 64a is provided between the first vertical movement portion 61a and the first base portion 67a. The first vertical movement portion spring 64a biases the first vertical movement portion 61a in a direction that is away from the first base portion 67a.

One end portion of the first link 65a is attached to the first vertical movement portion 61a in a state of being rotatable about an axis that is parallel to the x direction. The other end portion of the first link 65a is attached to the first latch 69a in the state of being rotatable about an axis that is parallel to the x direction. The first link 65a converts a force in the z direction into a force in the y direction, moves the first latch 69a to the right side (a direction toward the floating plate 30) in the y direction when the first vertical movement portion 61a moves downward in the z direction, and moves the first latch 69a to the left side (a direction away from the floating plate 30) in the y direction when the first vertical movement portion 61a moves upward in the z direction.

The first vertical movement portion 61a is held by the first base portion 67a in a state of being movable in the z direction. The first base portion 67a holds the first latch base 68a. The first base portion 67a is attached to the pin block 20 by screwing or the like.

The first latch 69a is held by the first latch base 68a in a state of being movable in the y direction. The first latch base 68a may be formed integrally with the first base portion 67a.

The first latch 69a moves on the first latch base 68a in the y direction based on the operations of the first vertical movement portion 61a and the first link 65a. The distal end portion (the end portion on the side close to the floating plate 30) of the first latch 69a is located inside the frame 30b of the floating plate 30 or located outside the frame 30b when viewed from the z direction.

When no force is applied to the first vertical movement portion 61a downward in the z direction, that is, when the first vertical movement portion 61a is located at the uppermost point (one end portion of the movement range) of the movement range, the distal end portion of the first latch 69a is located outside the frame 30b when viewed from the z direction and does not overlap the peripheral edge portion of the substrate 101 of the package 100 that is placed on the floating plate 30. When the first vertical movement portion 61a is pressed to the lower side in the z direction by the pressing member 301, the first latch 69a moves to the right side in the y direction. At this time, the distal end portion of the first latch 69a moves from the outside to the inside of the frame 30b when viewed from the z direction.

When the first vertical movement portion 61a moves downward in the z direction from the uppermost point of the movement range, the amount increases by which the first latch 69a protrudes to the right side in the y direction. The amount by which the first latch 69a protrudes to the right side in the y direction means the amount by which the first latch 69a protrudes from the first latch base 68a (or the first base portion 67a) to the right side in the y direction. When the first vertical movement portion 61a reaches the lowest point (the other end portion of the movement range) of the movement range, the amount becomes maximum by which the first latch 69a protrudes to the right side in the y direction, and the region becomes maximum in which the first latch 69a overlaps the substrate 101 of the package 100 placed on the floating plate 30 as viewed from the z direction.

When the downward pressing in the z direction by the pressing member 301 is released, the first vertical movement portion 61a moves upward in the z direction from the lowest point of the movement range, and the amount decreases by which the first latch 69a protrudes to the right side in the y direction. At this time, due to a temperature difference or the like, the package 100 may stick to the pressing member 301, and the package 100 may also move upward in the z direction together with the pressing member 301.

However, when the package 100 is lifted upward in the z direction by the pressing member 301, the distal end portion of the first latch 69a is located inside the frame 30b when viewed from the z direction, and a state is maintained in which the distal end portion overlaps the peripheral edge portion of the substrate 101 of the package 100 placed on the floating plate 30. Further, when viewed from the x direction, a state is maintained in which the distal end portion of the first latch 69a is located between the pressing member 301 and the substrate 101.

That is, at least when the package 100 is lifted upward in the z direction by the pressing member 301, the distal end portion of the first latch 69a is located inside the frame 30b when viewed from the z direction, and overlaps the peripheral edge portion of the substrate 101 of the package 100 placed on the floating plate 30. Accordingly, the distal end portion of the first latch 69a comes into contact with the substrate 101, limits the substrate 101 from moving upward in the z direction with respect to the distal end portion of the first latch 69a, and pulls the package 100 away from the pressing member 301.

### Second Removal Mechanism 60b

The second removal mechanism 60b includes a second vertical movement portion 61b, a second vertical movement portion spring 64b, a second link 65b, a second base portion 67b, a second latch base 68b, and a second latch 69b (see FIG. 6).

The second vertical movement portion 61b is the upper portion of the second removal mechanism 60b, and is pressed downward in the z direction by the pressing member 301. The second vertical movement portion 61b is held by the second base portion 67b in a state of being movable in the z direction.

The second vertical movement portion 61b is provided in a position relationship satisfying the following conditions. At least a part of the second vertical movement portion 61b overlaps a part of the lower end portion of the pressing member 301 when viewed from the z direction, and the second vertical movement portion 61b does not overlap the lower end portion of the PNP head when viewed from the z direction.

The second vertical movement portion spring 64b is provided between the second vertical movement portion 61b and the second base portion 67b. The second vertical movement portion spring 64b biases the second vertical movement portion 61b in a direction that is away from the second base portion 67b.

One end portion of the second link 65b is attached to the second vertical movement portion 61b in a state of being rotatable about an axis that is parallel to the x direction. The other end portion of the second link 65b is attached to the second latch 69b in the state of being rotatable about an axis that is parallel to the x direction. The second link 65b converts a force in the z direction into a force in the y direction, moves the second latch 69b to the left side (a direction toward the floating plate 30) in the y direction when the second vertical movement portion 61b moves downward in the z direction, and moves the second latch 69b to the right side (a direction away from the floating plate 30) in the y direction when the second vertical movement portion 61b moves upward in the z direction.

The second vertical movement portion 61b is held by the second base portion 67b in a state of being movable in the z direction. The second base portion 67b holds the second latch base 68b. The second base portion 67b is attached to the pin block 20 by screwing or the like.

The second latch 69b is held by the second latch base 68b in a state of being movable in the y direction. The second latch base 68b may be formed integrally with the second base portion 67b.

The second latch 69b moves on the second latch base 68b in the y direction based on the operations of the second vertical movement portion 61b and the second link 65b. The distal end portion (the end portion on the side close to the floating plate 30) of the second latch 69b is located inside the frame 30b of the floating plate 30 or located outside the frame 30b when viewed from the z direction.

When no force is applied to the second vertical movement portion 61b downward in the z direction, that is, when the second vertical movement portion 61b is located at the uppermost point (one end portion of the movement range) of the movement range, the distal end portion of the second latch 69b is located outside the frame 30b when viewed from the z direction and does not overlap the peripheral edge portion of the substrate 101 of the package 100 that is placed on the floating plate 30. When the second vertical movement portion 61b is pressed to the lower side in the z direction by the pressing member 301, the second latch 69b moves to the left side in the y direction. At this time, the distal end portion of the second latch 69b moves from the outside to the inside of the frame 30b when viewed from the z direction.

When the second vertical movement portion 61b moves downward in the z direction from the uppermost point of the movement range, the amount increases by which the second latch 69b protrudes to the left side in the y direction. The amount by which the second latch 69b protrudes to the left side in the y direction means the amount by which the second latch 69b protrudes from the second latch base 68b (or the second base portion 67b) to the left side in the y direction. When the second vertical movement portion 61b reaches the lowest point (the other end portion of the movement range) of the movement range, the amount becomes maximum by which the second latch 69b protrudes to the left side in the y direction, and the region becomes maximum in which the second latch 69b overlaps the substrate 101 of the package 100 placed on the floating plate 30 as viewed from the z direction.

When the downward pressing in the z direction by the pressing member 301 is released, the second vertical movement portion 61b moves upward in the z direction from the lowest point of the movement range, and the amount decreases by which the second latch 69b protrudes to the left side in the y direction. At this time, due to a temperature difference or the like, the package 100 sticks to the pressing member 301, and the package 100 also moves upward in the z direction together with the pressing member 301.

However, when the package 100 is lifted upward in the z direction by the pressing member 301, the distal end portion of the second latch 69b is located inside the frame 30b when viewed from the z direction, and a state is maintained in which the distal end portion overlaps the peripheral edge portion of the substrate 101 of the package 100 placed on the floating plate 30. Further, when viewed from the x direction, a state is maintained in which the distal end portion of the second latch 69b is located between the pressing member 301 and the substrate 101.

That is, at least when the package 100 is lifted upward in the z direction by the pressing member 301, the distal end portion of the second latch 69b is located inside the frame 30b when viewed from the z direction, and overlaps the peripheral edge portion of the substrate 101 of the package 100 placed on the floating plate 30. Accordingly, the distal end portion of the second latch 69b comes into contact with the substrate 101, limits the substrate 101 from moving upward in the z direction with respect to the distal end portion of the second latch 69b, and pulls the package 100 away from the pressing member 301.

### Position Relationship Between First Removal Mechanism 60a and Second Removal Mechanism 60b

When viewed from the z direction, the first removal mechanism 60a and the second removal mechanism 60b are provided in a position relationship in which the floating plate 30 is sandwiched therebetween. In the present embodiment, an example is shown in which the first removal mechanism 60a is provided on the front side in the x direction and on the left side in the y direction in the peripheral edge portion of the upper surface of the pin block 20, and the second removal mechanism 60b is provided on the rear side in the x direction and the right side in the y direction. In this case, the floating plate 30 is sandwiched between the first removal mechanism 60a and the second removal mechanism 60b on the diagonal line of the substantially rectangular shape that indicates the outer shape of the pin block 20.

However, the first removal mechanism 60a and the second removal mechanism 60b may be provided in other places of the pin block 20. For example, the first removal mechanism 60a and the second removal mechanism 60b may sandwich the floating plate 30 in the y direction.

### Package 100

The package 100 includes a substrate 101 and an integrated heat spreader (IHS) 102. Circuit components such as a CPU and a memory are mounted on the substrate 101. The IHS 102 is mounted on the substrate 101 to form the package 100. The substrate 101 is an object to be inspected by the tester according to the present embodiment. The package 100 is placed on the floating plate 30.

Even in a state in which the amount is maximum by which the first latch 69a protrudes to the right side in the y direction, the distal end portion of the first latch 69a does not come into contact with the IHS 102 that is placed on the floating plate 30. Even in a state in which the amount is maximum by which the second latch 69b protrudes to the left side in the y direction, the distal end portion of the second latch 69b does not come into contact with the IHS 102 that is placed on the floating plate 30.

When the package 100 is brought close to the pin block 20 by the movement of the pressing member 301 in the z direction, the package 100 is electrically connected to the contact probe 50 that is accommodated in the pin block 20, and is electrically connected to the inspection substrate 201 of the tester via the contact probe 50.

### Position Relationship Between Hole and Electrode

When the socket 1 is attached to the tester, the electrode of the inspection substrate 201 overlaps the first hole 11 of the pin plate 10 when viewed from the z direction. When the package 100 is placed on the floating plate 30 by the PNP head of the handler or the like, the electrode of the substrate 101 of the package 100 overlaps the third hole 31 of the floating plate 30 when viewed from the z direction.

### Operation Procedure

Next, the operation procedure of the inspection will be described (see FIGS. 7 to 17). The members of the socket 1 shown in FIGS. 7 to 17 are simplified for easy understanding of the movement of the first link 65a and the like, and the shapes and the like of the members of the socket 1 shown in the perspective views of FIGS. 1 to 6 are simplified. In FIGS. 7 to 17, illustration of the circuit components mounted on the substrate 101, the internal structure of the IHS 102, and the cover 40 is omitted. Bold arrows shown in FIGS. 7 to 17 indicate the movement direction of the pressing member 301.

The socket 1 is assembled in advance by screwing or the like. Specifically, the assembly of the pin plate 10, the pin block 20, and the cover 40 is formed by screwing or the like, and the floating plate 30 is placed on the pin block 20 via the plate spring 23. The assembly of the pin plate 10, the pin block 20, and the cover 40 is fixed to the tester by screwing or the like. At this time, the lower end portion (the first plunger 51) of the contact probe 50 comes into contact with the inspection substrate 201 of the tester.

The package 100 is placed on the floating plate 30 by the PNP head of the handler or the like (a first state, see FIG. 7). In the first state, the pressing member 301 is not in contact with the first vertical movement portion 61a of the first removal mechanism 60a. The pressing member 301 is not in contact with the second vertical movement portion 61b of the second removal mechanism 60b. Therefore, the first vertical movement portion 61a and the second vertical movement portion 61b are located at the uppermost point of the movement range. The pressing member 301 is not in contact with the package 100.

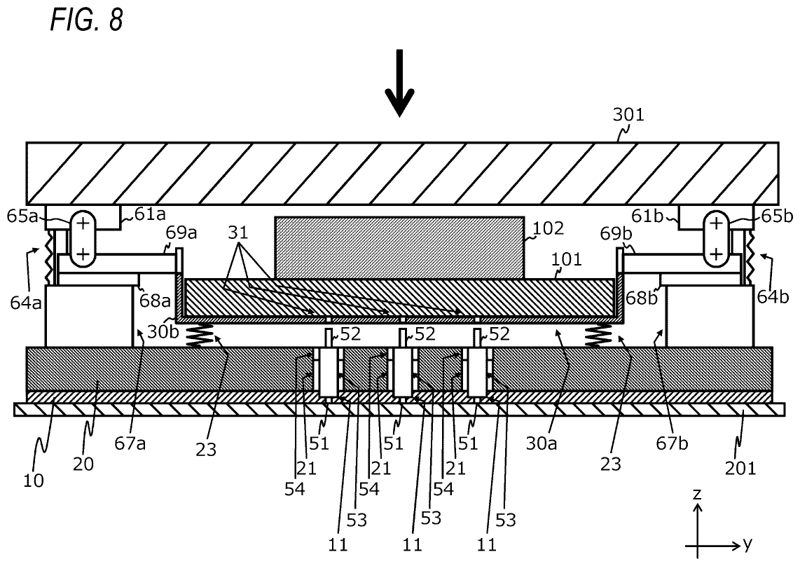

When the pressing member 301 moves from the first state to the lower side in the z direction, the pressing member 301 comes into contact with the first vertical movement portion 61a of the first removal mechanism 60a and the second vertical movement portion 61b of the second removal mechanism 60b (a second state, see FIG. 8). In the second state, the pressing member 301 is not in contact with the package 100.

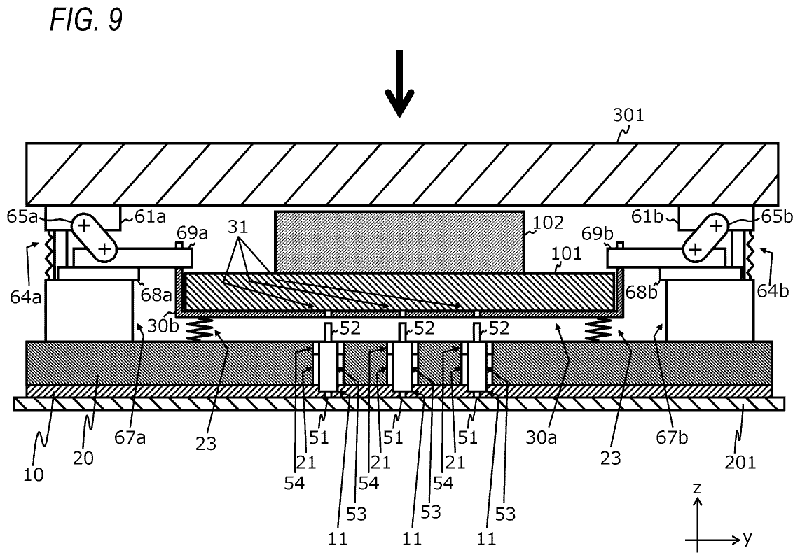

When the pressing member 301 moves further downward in the z direction from the second state, the pressing member 301 presses the first vertical movement portion 61a and the second vertical movement portion 61b downward in the z direction (a third state, see FIG. 9). The first vertical movement portion spring 64a and the second vertical movement portion spring 64b contract.

The first vertical movement portion 61a moves downward in the z direction, so that the first latch 69a moves to the right side (in a direction toward the floating plate 30) in the y direction via the first link 65a. Accordingly, a part of the first latch 69a overlaps the peripheral edge portion of the substrate 101 of the package 100 when viewed from the z direction. The second vertical movement portion 61b moves downward in the z direction, so that the second latch 69b moves to the left side (in a direction toward the floating plate 30) in the y direction via the second link 65b. Accordingly, a part of the second latch 69b overlaps the peripheral edge portion of the substrate 101 of the package 100 when viewed from the z direction.

In the third state, the pressing member 301 is not in contact with the package 100.

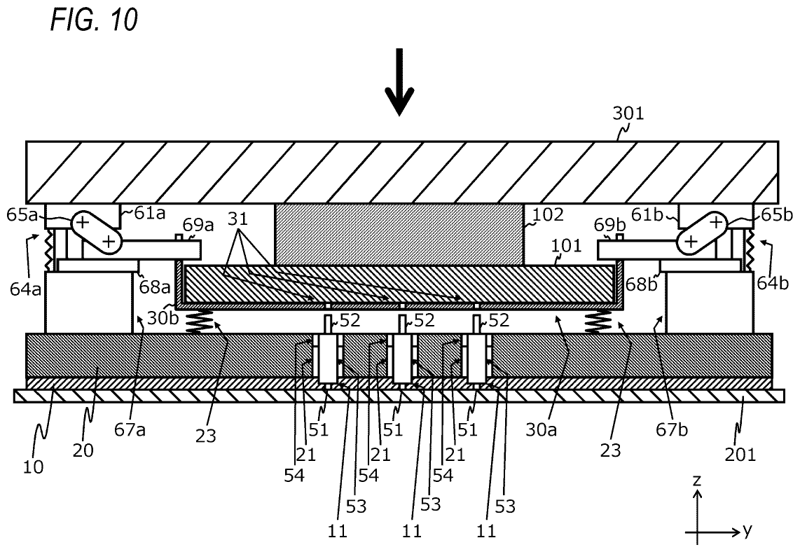

When the pressing member 301 moves further downward in the z direction from the third state, the pressing member 301 further presses the first vertical movement portion 61a and the second vertical movement portion 61b downward in the z direction (a fourth state, see FIG. 10). The first vertical movement portion spring 64a and the second vertical movement portion spring 64b further contract.

The first vertical movement portion 61a moves downward in the z direction, so that the first latch 69a further moves to the right side (in the direction toward the floating plate 30) in the y direction via the first link 65a. That is, the amount increases by which the first latch 69a protrudes to the right side in the y direction. The second vertical movement portion 61b moves downward in the z direction, so that the second latch 69b further moves to the left side (in the direction toward the floating plate 30) in the y direction via the second link 65b. That is, the amount increases by which the second latch 69b protrudes to the left side in the y direction.

The pressing member 301 comes into contact with the HS 102 of the package 1001.

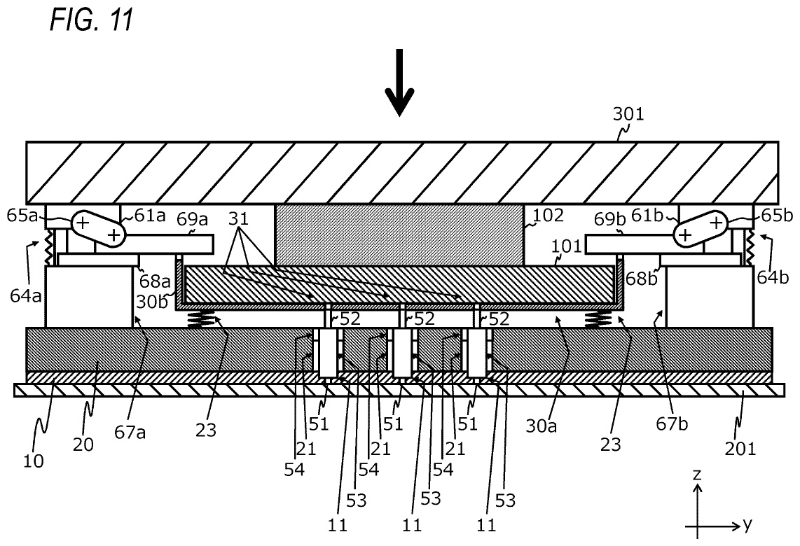

When the pressing member 301 moves further downward in the z direction from the fourth state, the pressing member 301 further presses the first vertical movement portion 61a and the second vertical movement portion 61b downward in the z direction (a fifth state, see FIG. 11). The first vertical movement portion spring 64a and the second vertical movement portion spring 64b further contract.

The first vertical movement portion 61a moves downward in the z direction, so that the first latch 69a further moves to the right side (in the direction toward the floating plate 30) in the y direction via the first link 65a. That is, the amount increases by which the first latch 69a protrudes to the right side in the y direction. The second vertical movement portion 61b moves downward in the z direction, so that the second latch 69b further moves to the left side (in the direction toward the floating plate 30) in the y direction via the second link 65b. That is, the amount increases by which the second latch 69b protrudes to the left side in the y direction.

The pressing member 301 presses the package 100 downward in the z direction. The package 100 moves downward in the z direction, so that the bottom plate 30a of the floating plate 30 is pressed downward in the z direction, and the plate spring 23 contracts.

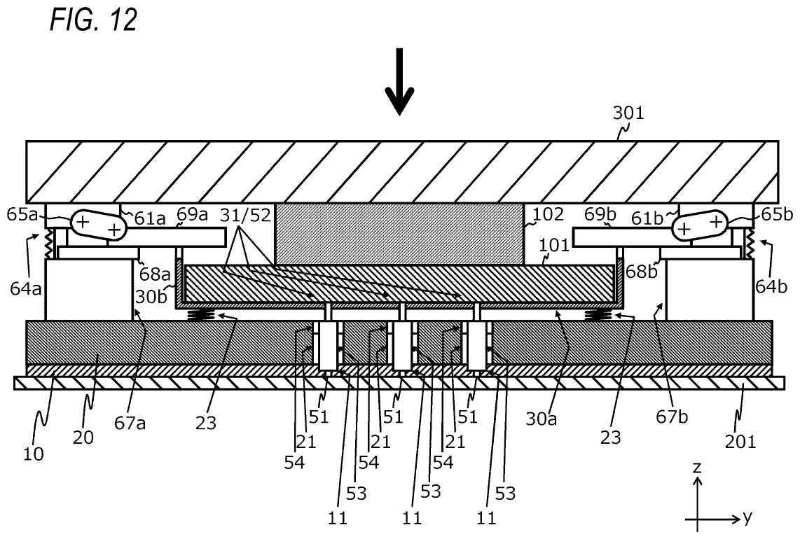

When the pressing member 301 moves further downward in the z direction from the fifth state, the pressing member 301 further presses the first vertical movement portion 61a and the second vertical movement portion 61b downward in the z direction (a sixth state, see FIG. 12). The first vertical movement portion spring 64a and the second vertical movement portion spring 64b further contract. The first vertical movement portion 61a and the second vertical movement portion 61b are located at the lowest point of the movement range.

The first vertical movement portion 61a moves downward in the z direction, so that the first latch 69a further moves to the right side (in the direction toward the floating plate 30) in the y direction via the first link 65a. That is, the amount becomes maximum by which the first latch 69a protrudes to the right side in the y direction, and the region becomes maximum in which the first latch 69a overlaps the substrate 101 of the package 100 placed on the floating plate 30 as viewed from the z direction. The second vertical movement portion 61b moves downward in the z direction, so that the second latch 69b further moves to the left side (in the direction toward the floating plate 30) in the y direction via the second link 65b. That is, the amount becomes maximum by which the second latch 69b protrudes to the left side in the y direction, and the region becomes maximum in which the second latch 69b overlaps the substrate 101 of the package 100 placed on the floating plate 30 as viewed from the z direction.

The pressing member 301 presses the package 100 downward in the z direction. The package 100 moves downward in the z direction, so that the bottom plate 30a of the floating plate 30 is pressed downward in the z direction, and the plate spring 23 further contracts. The second plunger 52 passes through the third hole 31 of the floating plate 30, protrudes upward in the z direction from the third hole 31 of the floating plate 30, and comes into contact with the lower surface of the substrate 101 of the package 100. The contact probe 50 is sandwiched between the substrate 101 of the package 100 and the inspection substrate 201 of the tester. The reaction force of the internal spring of the conductive tube 53 tends to push the first plunger 51 downward in the z direction, and tends to push the second plunger 52 upward in the z direction. Accordingly, the substrate 101 of the package 100, the contact probe 50, and the tester are electrically connected, and the package 100 is inspected in this state.

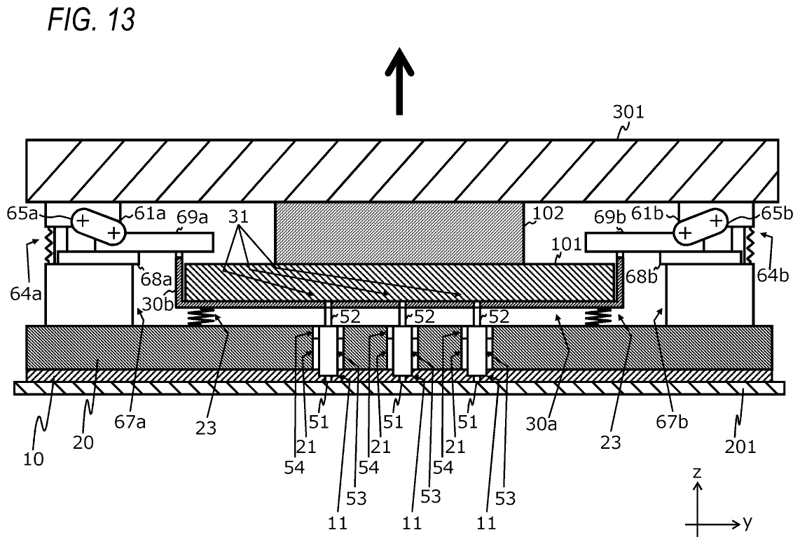

When the inspection is finished and the pressing member 301 moves upward in the z direction from the sixth state, the reaction force of the first vertical movement portion spring 64a presses the first vertical movement portion 61a upward in the z direction, and the reaction force of the second vertical movement portion spring 64b presses the second vertical movement portion 61b upward in the z direction (a seventh state, see FIG. 13).

The first vertical movement portion 61a moves upward in the z direction, so that the first latch 69a moves to the left side (in a direction away from the floating plate 30) in the y direction via the first link 65a. That is, the amount decreases by which the first latch 69a protrudes to the right side in the y direction. The second vertical movement portion 61b moves upward in the z direction, so that the second latch 69b moves to the right side (in the direction away from the floating plate 30) in the y direction via the second link 65b. That is, the amount decreases by which the second latch 69b protrudes to the left side in the y direction.

The package 100 is pulled out in a state (a frozen state) of sticking to the pressing member 301, and moves upward in the z direction together with the pressing member 301. The package 100 moves upward in the z direction, so that the reaction force of the plate spring 23 presses the floating plate 30 upward in the z direction.

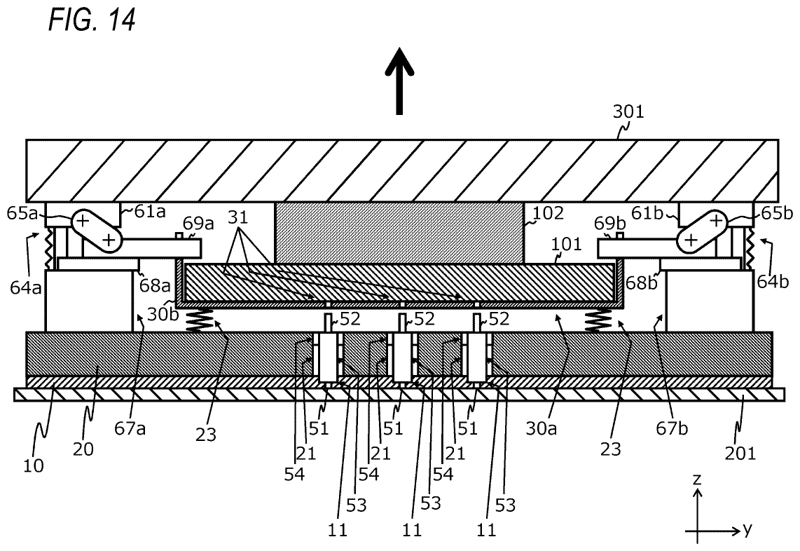

When the pressing member 301 moves further upward in the z direction from the seventh state, the reaction force of the first vertical movement portion spring 64a presses the first vertical movement portion 61a further upward in the z direction, and the reaction force of the second vertical movement portion spring 64b presses the second vertical movement portion 61b further upward in the z direction (an eighth state, see FIG. 14).

The first vertical movement portion 61a moves upward in the z direction, so that the first latch 69a further moves to the left side (in the direction away from the floating plate 30) in the y direction via the first link 65a. That is, the amount decreases by which the first latch 69a protrudes to the right side in the y direction. The second vertical movement portion 61b moves upward in the z direction, so that the second latch 69b further moves to the right side (in the direction away from the floating plate 30) in the y direction via the second link 65b. That is, the amount decreases by which the second latch 69b protrudes to the left side in the y direction.

The package 100 moves further upward in the z direction together with the pressing member 301 in the frozen state. The package 100 moves upward in the z direction, so that the reaction force of the plate spring 23 presses the floating plate 30 further upward in the z direction.

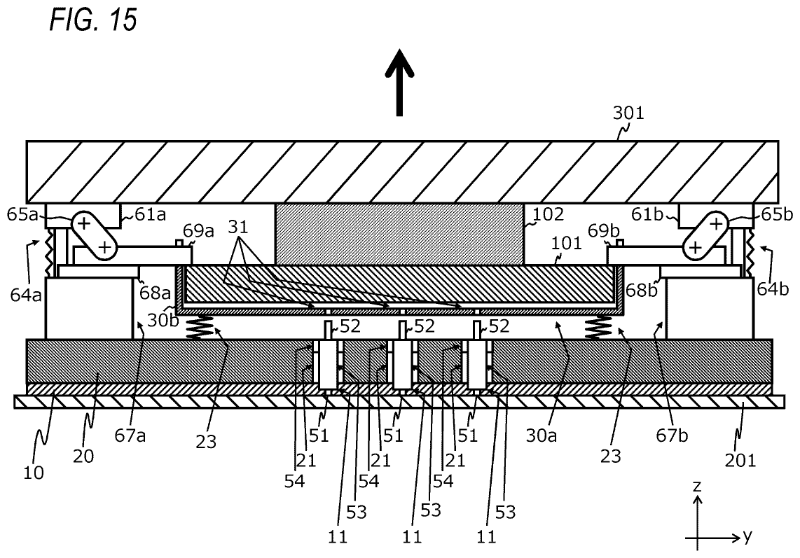

When the pressing member 301 moves further upward in the z direction from the eighth state, the reaction force of the first vertical movement portion spring 64a presses the first vertical movement portion 61a further upward in the z direction, and the reaction force of the second vertical movement portion spring 64b presses the second vertical movement portion 61b further upward in the z direction (a ninth state, see FIG. 15).

The first vertical movement portion 61a moves upward in the z direction, so that the first latch 69a further moves to the left side (in the direction away from the floating plate 30) in the y direction via the first link 65a. That is, the amount decreases by which the first latch 69a protrudes to the right side in the y direction. However, in the ninth state, a part of the first latch 69a also overlaps the peripheral edge portion of the substrate 101 of the package 100 when viewed from the z direction. The second vertical movement portion 61b moves upward in the z direction, so that the second latch 69b further moves to the right side (in the direction away from the floating plate 30) in the y direction via the second link 65b. That is, the amount decreases by which the second latch 69b protrudes to the left side in the y direction. However, in the ninth state, a part of the second latch 69b also overlaps the peripheral edge portion of the substrate 101 of the package 100 when viewed from the z direction.

The package 100 moves further upward in the z direction together with the pressing member 301 in the frozen state. Since the peripheral edge portion of the substrate 101 of the package 100 comes into contact with the first latch 69a and the second latch 69b, further upward movement of the package 100 in the z direction is limited. The package 100 moves upward in the z direction, so that the reaction force of the plate spring 23 presses the floating plate 30 further upward in the z direction.

When the pressing member 301 moves further upward in the z direction with respect to the ninth state due to the first latch 69a and the second latch 69b limiting further upward movement in the z direction, the package 100 is pulled away from the pressing member 301.

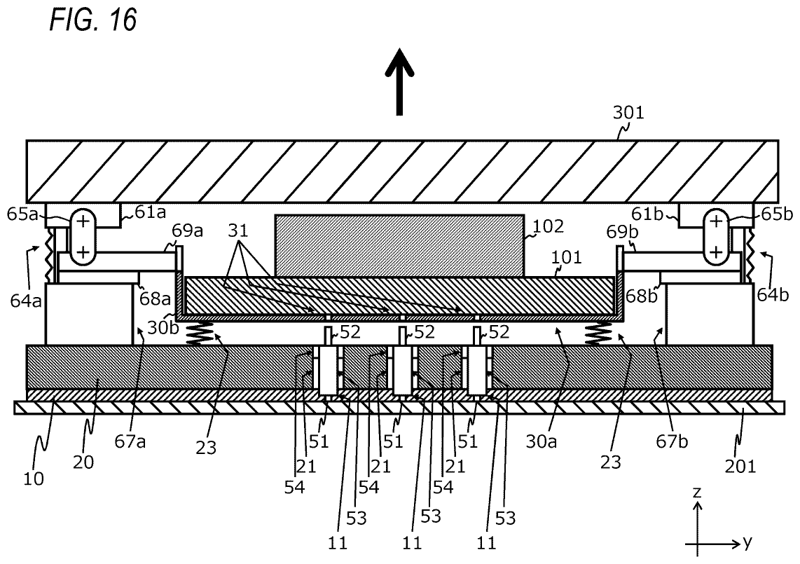

When the pressing member 301 moves further upward in the z direction from the ninth state, the reaction force of the first vertical movement portion spring 64a presses the first vertical movement portion 61a further upward in the z direction, and the reaction force of the second vertical movement portion spring 64b presses the second vertical movement portion 61b further upward in the z direction (a tenth state, see FIG. 16).

The first vertical movement portion 61a moves upward in the z direction, so that the first latch 69a further moves to the left side (in the direction away from the floating plate 30) in the y direction via the first link 65a. That is, the amount decreases by which the first latch 69a protrudes to the right side in the y direction. Accordingly, the first latch 69a retreats from a position where at least a part of the first latch 69a overlaps the peripheral edge portion of the substrate 101 of the package 100 when viewed from the z direction to a position where the first latch 69a does not overlap the peripheral edge portion of the substrate 101 of the package 100 when viewed from the z direction. The second vertical movement portion 61b moves upward in the z direction, so that the second latch 69b further moves to the right side (in the direction away from the floating plate 30) in the y direction via the second link 65b. That is, the amount decreases by which the second latch 69b protrudes to the left side in the y direction. Accordingly, the second latch 69b retreats from a position where at least a part of the second latch 69b overlaps the peripheral edge portion of the substrate 101 of the package 100 when viewed from the z direction to a position where the second latch 69b does not overlap the peripheral edge portion of the substrate 101 of the package 100 when viewed from the z direction.

The package 100 is separated from the pressing member 301, falls downward in the z direction, and is placed on the floating plate 30.

After the package 100 is in contact with the first latch 69a and the second latch 69b, it is desirable for the state to change from a state in which at least a part of the first latch 69a and at least a part of the second latch 69b overlap at least a part of the package 100 when viewed from the z direction to a state in which the first latch 69a and the second latch 69b do not overlap the package 100 when viewed from the z direction.

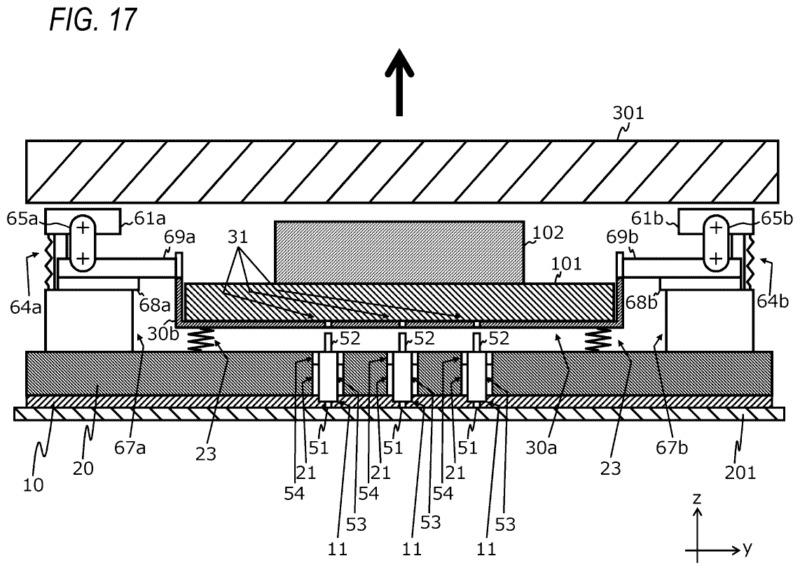

When the pressing member 301 further moves upward in the z direction from the tenth state, the pressing member 301 is separated from the first vertical movement portion 61a and the second vertical movement portion 61b (an eleventh state, see FIG. 17). Therefore, the first vertical movement portion 61a and the second vertical movement portion 61b are located at the uppermost point of the movement range.

### Effect of Releasing State in Which Package 100 Sticks to Pressing Member 301 Using First Latch 69a or the Like

When viewed in the z direction, a part of the latch (the first latch 69a and the second latch 69b) overlaps the peripheral edge portion of the substrate 101 of the package 100. Therefore, when the package 100 comes into contact with the latch (the first latch 69a and the second latch 69b), the substrate 101 is limited from moving upward in the z direction with respect to the distal end portion of the first latch 69a and the distal end portion of the second latch 69b. That is, movement of the package 100 in the z direction is limited. Then, the package 100 that sticks to the pressing member 301 is pulled away from the pressing member 301 by the latch (the first latch 69a and the second latch 69b). Accordingly, the package 100 can be prevented from moving together with the pressing member 301 when the pressing member 301 retreats.

This can be achieved by simply adding the removal device (the first removal mechanism 60a and the second removal mechanism 60b) including the latch (the first latch 69a and the second latch 69b) to the socket 1 without changing the structures of the package 100, the handler, and the tester.

### Effect of Package 100 Electrically Connecting with Contact Probe 50 when Brought Close to Pin Block 20

By movement of the pressing member 301 in the z direction, on and off control of electrical connection between the package 100 and the contact probe 50 can be executed.

### Effect of Using Link (First Link 65a and Second Link 65b

The removal device (the first removal mechanism 60a and the second removal mechanism 60b) can be implemented by a simple configuration using the link (the first link 65a and the second link 65b) or the like that converts the direction in which the force is applied from the z direction to the y direction.

### Effect of Removal Portion 60 Including Two Removal Devices (First Removal Mechanism 60a and Second Removal Mechanism 60b

Since movement of the package 100 is limited by the two contact points, the package 100 can be more reliably pulled away from the pressing member 301 as compared to a form in which the removal portion 60 includes only one removal device.

In particular, in the present embodiment, the floating plate 30 is sandwiched between the first removal mechanism 60a and the second removal mechanism 60b on the diagonal line of the substantially rectangular shape that indicates the outer shape of the pin block 20. That is, the pressing member 301 comes into contact at a location that is away from the center of the package 100 when viewed from the z direction. Therefore, the package 100 can be more reliably separated from the pressing member 301 as compared to a form in which the first removal mechanism 60a and the second removal mechanism 60b are provided at other positions. As compared to the form in which the first removal mechanism 60a and the second removal mechanism 60b are provided at other positions, it is easy to arrange the first removal mechanism 60a and the second removal mechanism 60b so as to avoid coming into contact with the device (the PNP head or the like) that conveys the package 100.

### Effect of Releasing Overlap Between First Latch 69a and the Like and Package 100 as Viewed from z Direction After Contact

As compared to a form in which the first latch 69a and the second latch 69b do not overlap the package 100 when viewed from the z direction when the package 100 is in contact with the first latch 69a and the second latch 69b, the package 100 can be reliably pulled away from the pressing member 301 by the first latch 69a and the second latch 69b.

### Another Embodiment: Number of Removal Devices

In the present embodiment, the removal portion 60 includes two removal devices (the first removal mechanism 60a and the second removal mechanism 60b). However, the removal portion 60 may include only one removal device or may include three or more removal devices.

### Another Embodiment: Pressing Member 301 Other than Cold Plate

In the present embodiment, a form has been described in which a cold plate that cools the IHS 102 of the package 100 is used as the pressing member 301 of the handler. Alternatively, a hot plate that heats the IHS 102 of the package 100 may be used as the pressing member 301 of the handler. A member that does not cause a temperature change in the IHS 102 of the package 100 may be used as the pressing member 301.

### Another Embodiment: Latch Movement Portion Other than Link

In the present embodiment, a form has been described in which the force applied in the upper-lower direction (the z direction) is converted into the force in the horizontal direction (the y direction) using the link (the first link 65a and the second link 65b). However, the force applied in the upper-lower direction (the z direction) may be converted into the force in the horizontal direction (the y direction) using another mechanism such as a hydraulic device instead of the link.

### Another Embodiment: Application Example of Member that Holds Package 100

In the present embodiment, a form has been described in which the member (the floating plate 30) that holds the package 100 is held by the pin block 20 in a state of being movable in the z direction via the plate spring 23. Alternatively, a plate corresponding to the floating plate 30 may be fixed to the pin block 20.

### Another Embodiment: Application Example of Spring

In the present embodiment, a form has been described in which, as the elastic member, the plate spring 23 is provided between the pin block 20 and the floating plate 30, the first vertical movement portion spring 64a is provided between the first vertical movement portion 61a and the first base portion 67a, the second vertical movement portion spring 64b is provided between the second vertical movement portion 61b and the second base portion 67b, and the internal spring is housed in the conductive tube 53. However, the extendable member is not limited to the spring, and other elastic members may be used as long as the member is extendable in the z direction.

### Another Embodiment: Application Example of Direction

In the present embodiment, a form has been described in which the pressing direction (the first direction) of the package 100 is the upper-lower direction (the z direction) and the movement direction (the second direction) of the first latch 69a and the second latch 69b is the horizontal direction (the y direction). Alternatively, the pressing direction may be a direction that is different from the upper-lower direction, and the movement direction may be the horizontal direction or a direction that is different from the horizontal direction.

### Another Embodiment: Application Example of Pulling away Using Latch

In the present embodiment, a form has been described in which the socket 1 includes the latch (the first latch 69a or the like), and the latch limits movement of the package 100 and pulls the package 100 away from the pressing member 301 (releases the sticking state). Alternatively, a device that is different from the socket 1 may include a latch, and the latch may limit movement of the object to be held and pulls the object to be held away from the pressing member.

In this case, the device includes a first member corresponding to the pin block 20, a second member corresponding to the floating plate 30, and the removal portion 60. The second member holds an object to be held corresponding to the package 100. The object to be held is electrically connected to a third member corresponding to the contact probe 50 when the object to be held is brought close to the first member by movement of a pressing member corresponding to the pressing member 301 of the handler or the like in the first direction (the z direction). The removal device (the first removal mechanism 60a or the like) includes a latch (the first latch 69a or the like) that moves in the second direction (the y direction) different from the first direction in conjunction with movement of the pressing member in the first direction. When the object to be held is moved (pulled out) by the pressing member from the first member in the first direction and in the direction (the upward direction) opposite to the pressing direction, at least a part of the latch overlaps at least a part (the peripheral edge portion of the substrate 101) of the object to be held when viewed from the first direction. That is, when the object to be held moves away from the first member, at least a part of the removal portion overlaps at least a part of the object to be held when viewed from the first direction.

### Effect of Releasing State in Which Object to be Held Sticks to Pressing Member Using Latch

When viewed from the first direction (the z direction), at least a part of the latch (the first latch 69a and the like) overlaps at least a part of the object to be held. Therefore, movement of the object to be held in the first direction is limited by the object to be held coming into contact with the latch. Then, the object to be held that sticks to the pressing member is pulled away from the pressing member by the latch. Accordingly, when the pressing member retreats, the object to be held can be limited from moving together with the pressing member.

### Another Embodiment: Application Example of Electrical Connection

In the present embodiment, a form has been described in which, when the object to be held corresponding to the package 100 is brought close to the first member corresponding to the pin block 20 by the pressing member 301, the third member corresponding to the contact probe 50 and the object to be held are electrically connected via the second member corresponding to the floating plate 30. Alternatively, the third member may be omitted, and the present invention may be applied to a device that does not have a configuration for electrically connecting the third member to the object to be held.

While certain embodiments of the present invention are described, these embodiments are presented by way of example only, and are not intended to limit the scope of the present invention. These embodiments can be implemented in various other forms, and various omissions, replacements, and modifications can be made without departing from the gist of the invention. These embodiments and modifications thereof are included in the scope of the invention and the gist of the invention, and are included in the invention described in the claims and a scope equivalent thereto.

According to the present specification, a device according to the following aspects is provided.

### Aspect 1

A device according to an aspect 1 includes: a first member; a second member held by the first member; and a removal portion provided in the first member, in which the second member holds an object to be held that is brought close to the first member by movement of a pressing member in a first direction, in which the removal portion moves in a second direction that is different from the first direction in conjunction with the movement of the pressing member in the first direction, and in which, when the object to be held moves away from the first member, at least a part of the removal portion overlaps at least a part of the object to be held when viewed in the first direction.

According to the above aspect, when viewed from the first direction, at least a part of the removal portion may overlap at least a part of the object to be held, and movement of the object to be held in the first direction may be limited. Further, the object to be held can be prevented from moving together with the pressing member when the object to be held moves away from the first member.

### Aspect 2

In an aspect 2, the object to be held is electrically connected to a third member that is stored in the first member when the object to be held is brought close to the first member by the movement of the pressing member in the first direction.

According to the above aspect, on and off control of electrical connection between the object to be held and the third member can be performed by the movement of the pressing member in the first direction.

### Aspect 3

In an aspect 3, the removal portion includes a movement portion, a link, and a latch that moves in the second direction in conjunction with the movement of the pressing member in the first direction, the movement portion moves in the first direction in conjunction with the movement of the pressing member in the first direction, the link moves the latch in the second direction when the movement portion moves in the first direction, and at least a part of the latch is located inside a peripheral edge portion of the second member or located outside the peripheral edge portion of the second member when viewed from the first direction by the movement portion and the link.

According to the above aspect, the removal portion can be implemented by a simple configuration using the link or the like that converts the direction in which a force is applied from the first direction to the second direction.

### Aspect 4

In an aspect 4, the removal portion includes two removal mechanisms, and the two removal mechanisms sandwich the second member when viewed from the first direction.

According to the above aspect, since the movement of the object to be held is limited by the two contact points, the object to be held can be more reliably pulled away from the pressing member as compared to a form in which the removal portion includes only one removal mechanism.

### Aspect 5

In an aspect 5, after the object to be held moves away from the first member and is separated from the pressing member, a state in which at least a part of the removal portion overlaps at least a part of the object to be held when viewed from the first direction is changed to a state in which the removal portion does not overlap the object to be held when viewed from the first direction.

According to the above aspect, when the object to be held is in a state of being separated from the pressing member, the object to be held can be more reliably pulled away from the pressing member by the removal portion as compared to a form in which the removal portion does not overlap the object to be held when viewed from the first direction.

### REFERENCE SIGNS LIST

1: socket (device)
10: pin plate
11: first hole
20: pin block (first member)
21: second hole
23: plate spring
30: floating plate (second member)
30a: bottom plate
30b: frame
31: third hole
40: cover
41: housing hole
50: contact probe (third member)
51: first plunger
52: second plunger
53: conductive tube
54: insulating member
60: removal portion
60a: first removal mechanism
60b: second removal mechanism
61a: first vertical movement portion
61b: second vertical movement portion
64a: first vertical movement portion spring
64b: second vertical movement portion spring
65a: first link
65b: second link
67a: first base portion
67b: second base portion
68a: first latch base
68b: second latch base
69a: first latch
69b: second latch
100: package (object to be held)
101: substrate
102: IHS
201: inspection substrate of tester
301: pressing member (cold plate and hot plate)

1. A device comprising:
a first member;
a second member held by the first member; and
a removal portion provided in the first member,
wherein the second member holds an object to be held that is brought close to the first member by movement of a pressing member in a first direction,
wherein the removal portion moves in a second direction that is different from the first direction in conjunction with the movement of the pressing member in the first direction, and
wherein, when the object to be held moves away from the first member, at least a part of the removal portion overlaps at least a part of the object to be held when viewed in the first direction.

2. The device according to claim 1,
wherein the object to be held is electrically connected to a third member that is stored in the first member when the object to be held is brought close to the first member by the movement of the pressing member in the first direction.

3. The device according to claim 1,
wherein the removal portion includes a movement portion, a link, and a latch that moves in the second direction in conjunction with the movement of the pressing member in the first direction,
wherein the movement portion moves in the first direction in conjunction with the movement of the pressing member in the first direction,
wherein the link moves the latch in the second direction when the movement portion moves in the first direction, and
wherein at least a part of the latch is located inside a peripheral edge portion of the second member when viewed from the first direction by the movement portion and the link.

4. The device according to claim 1,
wherein the removal portion includes two removal mechanisms, and
wherein the two removal mechanisms sandwich the second member when viewed from the first direction.

5. The device according to claim 1,
wherein, after the object to be held moves away from the first member and is separated from the pressing member, a state of the device is changed from a state in which at least a part of the removal portion overlaps at least a part of the object to be held when viewed from the first direction to a state in which the removal portion does not overlap the object to be held when viewed from the first direction.

6. The device according to claim 1,
wherein the removal portion includes a movement portion, a link, and a latch that moves in the second direction in conjunction with the movement of the pressing member in the first direction,
wherein the movement portion moves in the first direction in conjunction with the movement of the pressing member in the first direction,
wherein the link moves the latch in the second direction when the movement portion moves in the first direction, and
wherein at least a part of the latch is located outside the peripheral edge portion of the second member when viewed from the first direction by the movement portion and the link.
